(19) United States
(12) Patent Application Publication
(10) Pub. No.: US 2021/0098482 A1
(43) Pub. Date: Apr. 1, 2021

(54) SEMICONDUCTOR STRUCTURE AND MANUFACTURING METHOD THEREOF

(71) Applicant: MACRONIX INTERNATIONAL CO., LTD., HSINCHU (TW)

(72) Inventors: Kuan-Cheng LIU, Taichung City (TW); Cheng-Wei LIN, Hsinchu City (TW); Kuang-Wen LIU, HSINCHU (TW)

(21) Appl. No.: 16/584,999

(22) Filed: Sep. 27, 2019

(51) Int. Cl. H01L 27/11573; H01L 27/11568; H01L 27/11582; H01L 23/522; H01L 23/528; H01L 23/535; H01L 21/027; H01L 21/768

(52) U.S. Cl. CPC H01L 27/11573; H01L 27/11568; H01L 27/11582; H01L 23/5226; H01L 21/76877; H01L 23/535; H01L 21/0276; H01L 21/76895; H01L 21/76816; H01L 23/5283

(57) ABSTRACT

A semiconductor structure includes a substrate, at least one first conductive structure, at least one second conductive structure, at least one first memory structure, and at least one second memory structure. The substrate has an array region and a dummy region. The first conductive structure is disposed on the array region. The second conductive structure is disposed on the dummy region. The first memory structure is disposed on the first conductive structure. The first memory structure includes a first channel layer, and the first channel layer is in contact with the first conductive structure. The second memory structure is disposed on the second conductive structure. The second memory structure includes a second channel layer, and the second channel layer is isolated from the second conductive structure.

### BACKGROUND

### Field of Invention

The present disclosure relates to a semiconductor structure and a manufacturing method of the semiconductor structure.

### Description of Related Art

In recent years, the structures of semiconductor devices have been changed constantly, and the storage capacity of the devices has been increased continuously. Memory devices are used in storage elements for many products such as MP3 players, digital cameras, computer files, etc. As memory devices meet a bottleneck due to scaling limitation of photo patterning, changing the channel direction from two dimensions to three dimensions is a world trend.

At such three-dimensional (3D) memory devices, dummy strings are usually formed at the same time with array main strings for main stream process. As such, it is desirable to develop a three-dimensional memory device with strings which will not affect the performance of the device.

### SUMMARY

The disclosure relates in general to a semiconductor structure and a manufacturing method thereof.

According to an embodiment of the present disclosure, the semiconductor structure includes a substrate, at least one first conductive structure, at least one second conductive structure, at least one first memory structure, and at least one second memory structure. The substrate has an array region and a dummy region. The first conductive structure is disposed on the array region. The second conductive structure is disposed on the dummy region. The first memory structure is disposed on the first conductive structure. The first memory structure includes a first channel layer, and the first channel layer is in contact with the first conductive structure. The second memory structure is disposed on the second conductive structure. The second memory structure includes a second channel layer, and the second channel layer is isolated from the second conductive structure.

In an embodiment of the present disclosure, a number of the first memory structure is plural, and a number of the second memory structure is plural, and a distribution density of the first memory structures is higher than a distribution density of the second memory structures.

In an embodiment of the present disclosure, the semiconductor structure further includes a dielectric layer and a plurality of conductive layers. The dielectric layer is disposed on the substrate. The conductive layers are embedded in the dielectric layer. The first memory structure and the second memory structure penetrate through the dielectric layer and the conductive layers.

In an embodiment of the present disclosure, each of the conductive layers has a first segment and a second segment, the first segments are disposed on the array region, the second segments are disposed on the dummy region, and the second segments are in a staircase configuration.

In an embodiment of the present disclosure, the semiconductor structure further includes at least one contact structure penetrating through the dielectric layer and in contact with the second segment of one of the conductive layers.

In an embodiment of the present disclosure, the first memory structure further includes a first memory structure layer, a first isolation structure, and a first conductive plug layer. A portion of the first channel layer is between the first memory structure layer and the first isolation structure, and a portion of the first channel layer penetrates through a bottom portion of the first memory structure layer. The first conductive plug layer is disposed on the first isolation structure, and the first conductive plug layer is in contact with the first channel layer.

In an embodiment of the present disclosure, the first memory structure layer includes a first blocking layer, a first memory storage layer, and a first tunneling layer. The first blocking layer is disposed on sidewalls of the conductive layers and the dielectric layer. The first memory storage layer is disposed on the first blocking layer. The first tunneling layer is disposed on the first memory storage layer.

In an embodiment of the present disclosure, the second memory structure further includes a second memory structure layer, a second isolation structure, and a second conductive plug layer. The second channel layer is between the second memory structure layer and the second isolation structure. The second conductive plug layer is disposed on the second isolation structure, and the second conductive plug layer is in contact with the second channel layer.

In an embodiment of the present disclosure, the second memory structure layer includes a second blocking layer, a second memory storage layer, and a second tunneling layer. The second blocking layer is disposed on sidewalls of the conductive layers and the dielectric layer and on the second conductive structure. The second memory storage layer is disposed on the second blocking layer. The second conductive plug layer is disposed on the second isolation structure, and the second conductive plug layer is in contact with the second channel layer.

In an embodiment of the present disclosure, the first conductive structure and the second conductive structure are epitaxial structures.

According to an embodiment of the present disclosure, a manufacturing method of a semiconductor structure includes the following steps of: forming at least one first trench on an array region of a substrate and at least one second trench on a dummy region of the substrate; forming at least one first conductive structure in the first trench and at least one second conductive structure in the second trench; forming at least one first memory structure layer in the first trench and at least one second memory structure layer in the second trench; disposing a mask stack covering the second trench and the second memory structure layer; deepening the first trench, such that the first conductive structure is exposed by the first memory structure layer; removing the mask stack; and forming a first channel layer on the first memory structure layer and a second channel layer on the second memory structure layer, in which the first channel layer is in contact with the first conductive structure.

In an embodiment of the present disclosure, the manufacturing method further includes: forming a dielectric layer and a plurality of insulating layers on the substrate, in which the insulating layers are embedded in the dielectric layer; and replacing the insulating layers respectively with a plurality of conductive layers.

In an embodiment of the present disclosure, forming the dielectric layer and the insulating layers on the substrate includes: forming a plurality of dielectric sublayers and the insulating layers interlaced and stacked on the substrate; removing portions of the dielectric sublayers and portions of the insulating layers on the dummy region to form a space; and refilling the space with a material of the dielectric sublayers such that the insulating layers are formed in a staircase configuration.

In an embodiment of the present disclosure, forming the first trench on the array region of the substrate and the second trench on the dummy region of the substrate includes: forming the first trench and the second trench penetrating through the dielectric layer and the insulating layers.

In an embodiment of the present disclosure, the manufacturing method further includes: forming at least one contact structure penetrating through the dielectric layer and in contact with one of the conductive layers.

In an embodiment of the present disclosure, forming the first memory structure layer in the first trench and the second memory structure layer in the second trench includes: forming a first blocking layer in the first trench and a second blocking layer in the second trench; forming a first memory storage layer on the first blocking layer and a second memory storage layer on the second blocking layer; and forming a first tunneling layer on the first memory storage layer and a second tunneling layer on the second memory storage layer.

In an embodiment of the present disclosure, the manufacturing method further includes: forming a first sacrificial layer on the first memory structure layer and a second sacrificial layer on the second memory structure layer; and removing the first sacrificial layer and the second sacrificial layer.

In an embodiment of the present disclosure, deepening the first trench includes: removing a bottom portion of the first memory structure layer and a bottom portion of the first sacrificial layer, such that the first conductive structure is exposed by the first memory structure layer and the first sacrificial layer.

In an embodiment of the present disclosure, the manufacturing method further includes: forming a first isolation structure on the first channel layer and a second isolation structure on the second channel layer; and replacing a top portion of the first isolation structure and a top portion of the second isolation structure respectively with a first conductive plug layer and a second conductive plug layer, such that that the first conductive plug layer is in contact with the first channel layer, and the second conductive plug layer is in contact with the second channel layer.

In an embodiment of the present disclosure, disposing the mask stack covering the second trench and the second memory structure layer includes: disposing a pattering layer covering the second trench and the second memory structure layer; disposing an antireflective coating layer on the pattering layer;

and disposing a photoresist layer on the antireflective coating layer.

In the aforementioned embodiments of the present disclosure, since the second channel layer of the second memory structure is isolated from the second conductive structure, contact short to the second memory structure through the contact structure is avoided, and hence fake signals caused by array breakdown and word line leak are prevented. Furthermore, the aforementioned embodiments of the present disclosure also provide a method of disposing a mask stack covering the second trench while deepening the first trench, such that the second channel layer formed subsequently in the second trench is isolated from the second conductive structure, thereby forming the second memory structure without any electrical function.

### BRIEF DESCRIPTION OF THE DRAWINGS

The disclosure can be more fully understood by reading the following detailed description of the embodiments, with reference made to the accompanying drawings as follows:

FIG. 1 is a cross-sectional view of a semiconductor structure according to an embodiment of the present disclosure; and

FIGS. 2, 3, 4, 5, 6, 7, 8, 9A, 10, 11, 12, 13, 14, 15, 16, 17, 18, 19, 20, 21, 23, and 24 are cross-sectional views of a process at various stages of a manufacturing method of a semiconductor structure according to an embodiment of the present disclosure.

FIG. 9B is a cross-sectional view of a process at various stages of a manufacturing method of a semiconductor structure according to another embodiment of the present disclosure.

FIG. 22 is a partial enlargement diagram of FIG. 21.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

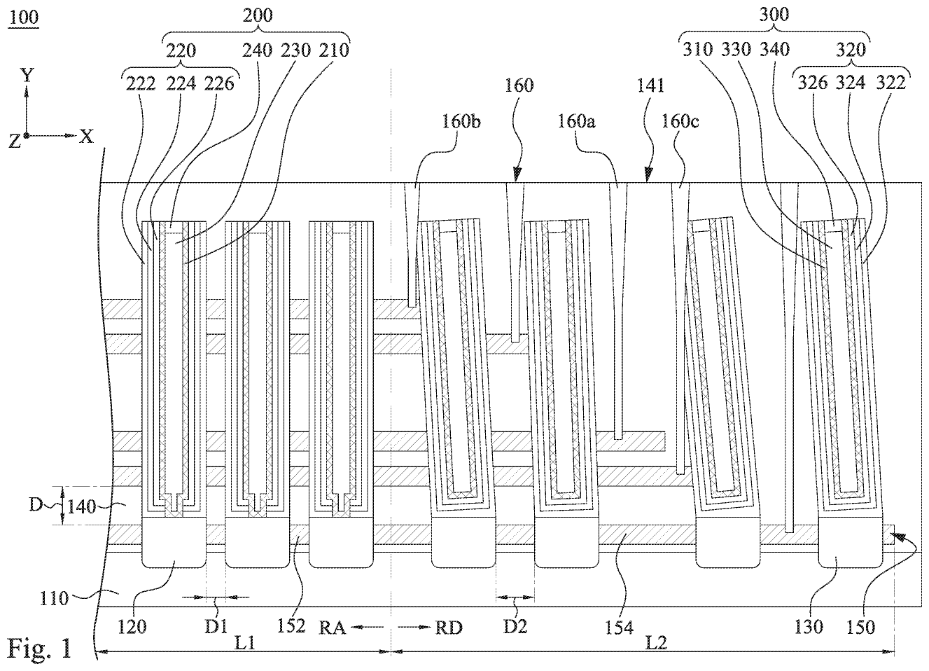

FIG. 1 is a cross-sectional view of a semiconductor structure 100 according to an embodiment of the present disclosure. Reference is made to FIG. 1, in which a semiconductor structure 100 includes a substrate 110, at least one first conductive structure 120, at least one second conductive structure 130, at least one first memory structure 200, and at least one second memory structure 300. The substrate 110 has an array region RA and a dummy region RD. The first conductive structure 120 is disposed on the array region RA. The second conductive structure 130 is disposed on the dummy region RD. The first memory structure 200 is disposed on the first conductive structure 120. The first memory structure 200 includes a first channel layer 210, and the first channel layer 210 is in contact with the first conductive structure 120. The second memory structure 300 is disposed on the second conductive structure 130. The second memory structure 300 includes a second channel layer 310, and the second channel layer 310 is isolated from the second conductive structure 130. In some embodiments of the present disclosure, the first conductive structure 120 and the second conductive structure 130 are epitaxial structures, and the first channel layer 210 and the second channel layer 310 may be made of a material including undoped polysilicon, but the present disclosure is not limited in this regard.

In some embodiments of the present disclosure, the semiconductor structure 100 further includes a dielectric layer 140 and a plurality of conductive layers 150. The dielectric layer 140 is disposed on the substrate 110, and the conductive layers 150 are embedded in the dielectric layer 140. The conductive layers 150 may serve as word lines (WLs). A distance D between each of the conductive layers 150 may be different, but the present disclosure is not limited in this regard. Each of the conductive layers 150 has a first segment 152 and a second segment 154, the first segments 152 are disposed on the array region RA, and the second segments 154 are disposed on the dummy region RD. In other words, the conductive layers 150 extend across the array region RA and the dummy region RD. Furthermore, a length L1 of each of the first segments 152 may be identical to each other, and a length L2 of each of the second segments 154 may be different from each other. For example, a length L2 of each of the second segments 154 may decrease progressively from a bottommost segment of the second segments 154 to a topmost segment of the second segments 154, such that the second segments 154 of the conductive layers 150 on the dummy region RD are in a staircase configuration.

In some embodiments of the present disclosure, the first memory structure 200 and the second memory structure 300 penetrate through the dielectric layer 140 and the conductive layers 150. Furthermore, the conductive structures (including the first conductive structure 120 and the second conductive structure 130), the first memory structure 200, and the conductive layers 150 extend in directions perpendicular to each other. As shown in FIG. 1, the conductive layers 150 extend along the X axis, the first memory structure 200 extends along the Y axis, and the conductive structures extend along the Z axis. Additionally, the second memory structure 300 extends along the plane formed by the X axis and the Y axis. For example, an angle between the extending direction of the second memory structure 300 and the extending direction of the substrate 110 (or the conductive layers 150) may be an acute angle smaller than 90°.

In some embodiments of the present disclosure, a number of the first memory structure 200 is plural, and a number of the second memory structure 300 is plural. Since the second segments 154 of the conductive layers 150 are in a staircase configuration, each of the second memory structures 300 on the dummy region RD may penetrate through different numbers of the conductive layers 150. In detail, the second memory structures 300 closer to the array region RA may penetrate through more conductive layers 150, and the second memory structures 300 far away from the array region RA may penetrate through less conductive layers 150. Additionally, a distance D1 between each of the first memory structures 200 is smaller than a distance D2 between each of the second memory structures 300, and hence a distribution density of the first memory structures 200 is higher than a distribution density of the second memory structures 300.

In some embodiments of the present disclosure, the first memory structure 200 further includes a first memory structure layer 220. The first memory structure layer 220 includes a first blocking layer 222, a first memory storage layer 224, and a first tunneling layer 226. The first blocking layer 222 is disposed on sidewalls of the conductive layers 150 and the dielectric layer 140. The first memory storage layer 224 is disposed on the first blocking layer 222. The first tunneling layer 226 is disposed on the first memory storage layer 224. In some embodiments of the present disclosure, the first blocking layer 222 and the first tunneling layer 226 may be made of a material including silicon oxide or other dielectric, and the first memory storage layer 224 may be made of a material including silicon nitride or other material that is able to trap electrons, but the present disclosure is not limited in this regard.

The first memory structure 200 further includes a first isolation structure 230 and a first conductive plug layer 240. A portion of the first channel layer 210 is between the first memory structure layer 220 and the first isolation structure 230, and a portion of the first channel layer 210 penetrates through a bottom portion of the first memory structure layer 220 to be in contact with the first conductive structure 120. In some embodiments of the present disclosure, the second isolation structure 230 may be made of a material including silicon oxide or other dielectric. Since the first conductive structure 120 is electrically connected to a ground source line (GSL), the first memory structure 200 is electrically connected to the ground source line through the first channel layer 210. Furthermore, the first conductive plug layer 240 is disposed on the first isolation structure 230, and the first conductive plug layer 240 is in contact with the first channel layer 210. The first conductive plug layer 240 may be made of a material including the same material as that of the first channel layer 210, such as doped polysilicon, but the present disclosure is not limited in this regard.

In some embodiments of the present disclosure, the second memory structure 300 further includes a second memory structure layer 320. The second memory structure layer 320 includes a second blocking layer 322, a second memory storage layer 324, and a second tunneling layer 326. The second blocking layer 322 is disposed on sidewalls of the conductive layers 150 and the dielectric layer 140. The second memory storage layer 324 is disposed on the second blocking layer 322. The second tunneling layer 326 is disposed on the second memory storage layer 324. In some embodiments of the present disclosure, the second blocking layer 322 and the second tunneling layer 326 may be made of a material including silicon oxide or other dielectric, and the second memory storage layer 324 may be made of a material including silicon nitride or other material that is able to trap electrons, but the present disclosure is not limited in this regard.

The second memory structure 300 further includes a second isolation structure 330 and a second conductive plug layer 340. The second channel layer 310 is between the second memory structure layer 320 and the second isolation structure 330. In some embodiments of the present disclosure, the second isolation structure 330 may be made of a material including silicon oxide or other dielectric. Since the second conductive structure 120 is electrically connected to a ground source line (GSL), and the second channel layer 310 is isolated from the second conductive structure 130 by the second memory structure layer 320, the second memory structure 300 is isolated from the ground source line (GSL). Furthermore, the second conductive plug layer 340 is disposed on the second isolation structure 330, and the second conductive plug layer 340 is in contact with the second channel layer 310. The second conductive plug layer 340 may be made of a material including the same material as that of the second channel layer 310, such as doped polysilicon, but the present disclosure is not limited in this regard.

In some embodiments of the present disclosure, the semiconductor structure 100 further includes at least one contact structure 160 disposed on the dummy region RD and penetrating through the dielectric layer 140 to be in contact with the second segment 154 of one of the conductive layers 150. As shown in FIG. 1, the contact structure 160 may be entirely separated from the second channel layer 310 such as 160a, near the second channel layer 310 such as 160b, or in contact with the channel layer 310 such as 160c. In some embodiments of the present disclosure, a number of the contact structure 160 may be plural, and some of the contact structures 160 may be entirely separated from the second channel layer 310, while the other of the contact structures 160 may be near or in contact with the second channel layer 310. Since the contact structure 160 is in contact with the second segment 154 of one of the conductive layers 150 and extends to a top surface 141 of the dielectric layer 140, the word line can be electrically connected to other signal lines, such as bit lines (BL), through the contact structure 160.

In the aforementioned embodiments of the present disclosure, since the second channel layer 310 of the second memory structure 300 is isolated from the second conductive structure 130, contact short to the second memory structure 300 through the contact structure 160 is avoided, and hence fake signals caused by array breakdown and word line leak are prevented. For example, when applying an input voltage of 20 volt to the semiconductor structure 100, the value of detected breakdown voltage can be continuously maintained at greater than approximate 20 volt. That is, the value of the detected breakdown voltage can be maintained stably in a certain range without dropping to further prevent shorting, and hence the semiconductor structure 100 is compliance with electrical specifications.

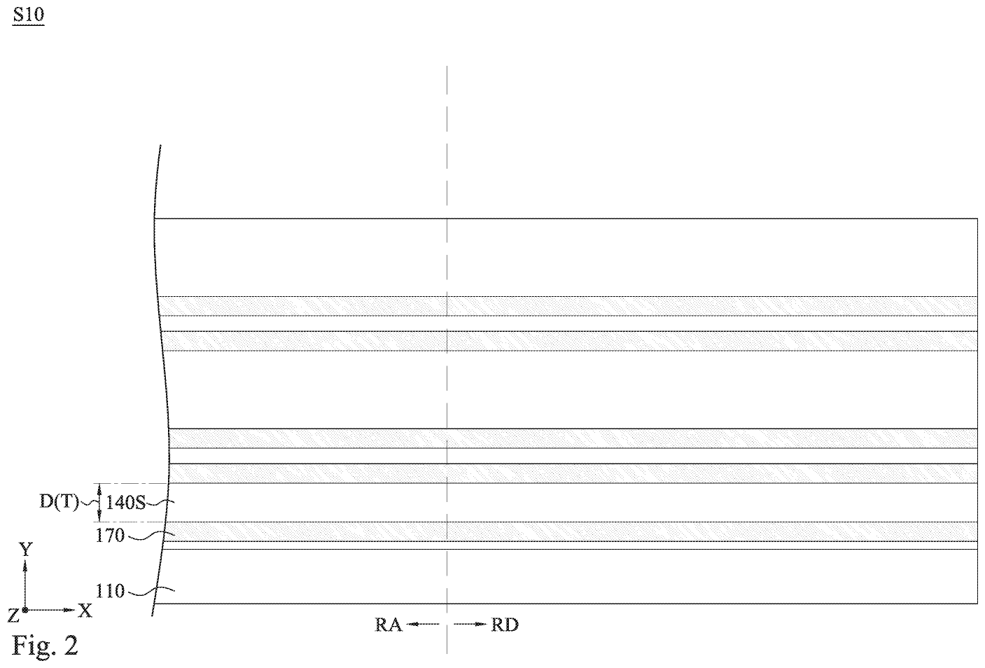

FIGS. 2, 3, 4, 5, 6, 7, 8, 9A, 10, 11, 12, 13, 14, 15, 16, 17, 18, 19, 20, 21, 23, and 24 are cross-sectional views of a process at various stages of a manufacturing method of a semiconductor structure according to an embodiment of the present disclosure. It is noted that the connection relationships, the materials, and the advantages of the elements described above will not be repeated. In the following description, a manufacturing method of a semiconductor structure 100 will be described.

Reference is made to FIG. 2, which is a cross-sectional view of step S10 of forming the semiconductor structure 100. In step S10, a substrate 110 having an array region RA and a dummy region RD is provided, and a plurality of insulating layers 170 and a plurality of dielectric sublayers 140S are interlaced and stacked on the substrate 110. In some embodiments of the present disclosure, a thickness T of each of the dielectric sublayers 140S may be different form each other. In other words, a distance D between each of the insulating layers 170 may be different from each other. Furthermore, the dielectric sublayers 140S may be made of a material including silicon oxide or other dielectric, and insulating layers 170 may be made of a material including silicon nitride, but the present disclosure is not limited in this regard.

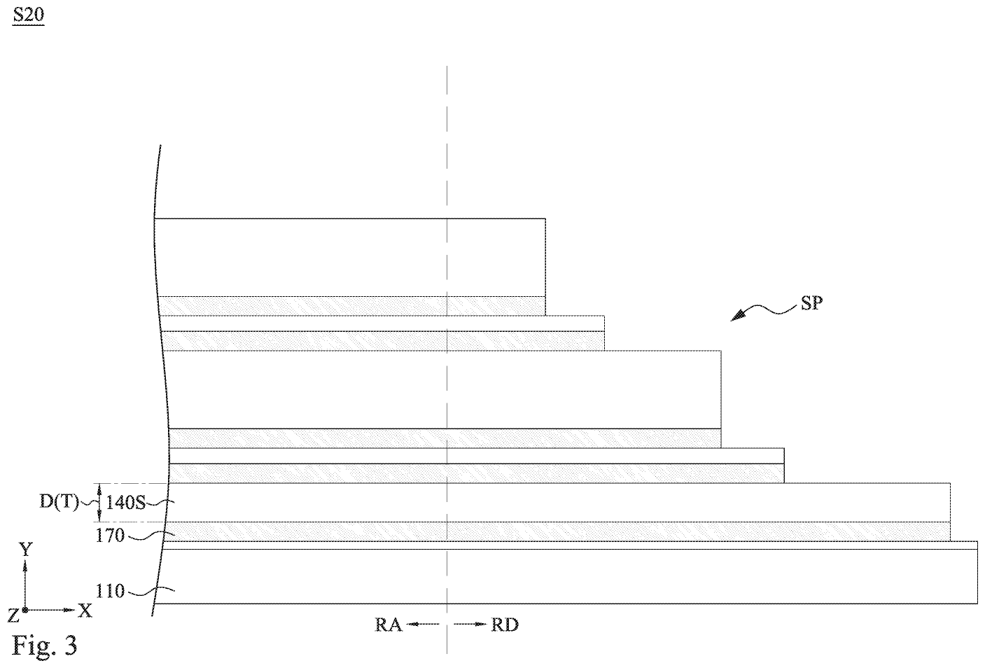

Reference is made to FIG. 3, which is a cross-sectional view of step S20 of forming the semiconductor structure 100. In step S20, after the stacked layers are provided on the substrate 110, portions of the dielectric sublayers 140S and portions of the insulating layers 170 on the dummy region RD is then removed to form a space SP. Furthermore, each of the insulating layers 170 and each of the dielectric sublayers 140S are removed in a different extent (e.g. length). For example, a larger extent of a topmost layer of the insulating layers 170 and a larger extent of a topmost layer of the dielectric sublayers 140S are removed while a smaller extent of a bottommost layer of the insulating layers 170 and a smaller extent of a bottommost layer of the dielectric sublayers 140S are removed, such that the remaining insulating layers 170 and the remaining dielectric sublayers 140S are formed in a staircase configuration.

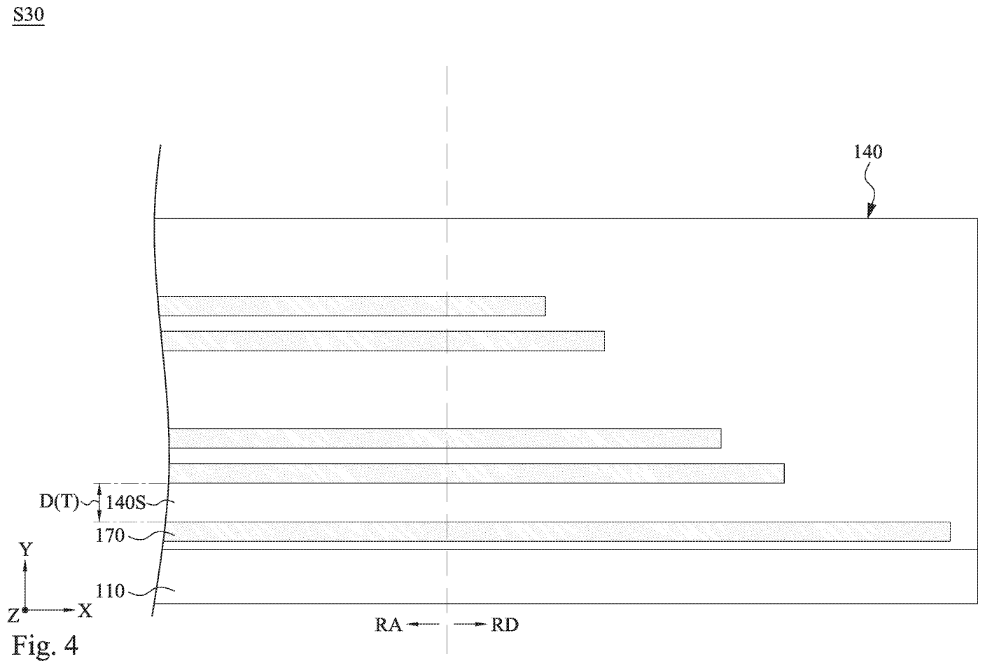

Reference is made to FIG. 4, which is a cross-sectional view of step S30 of forming the semiconductor structure 100. In step S30, the space SP on the dummy region RD is then refilled with the material of the dielectric sublayers 140S, such that a dielectric layer 140 is formed, and the insulating layers 170 with a staircase configuration are embedded in the dielectric layer 140. Furthermore, the insulating layers 170 extend across the array region RA and the dummy region RD of the substrate 110.

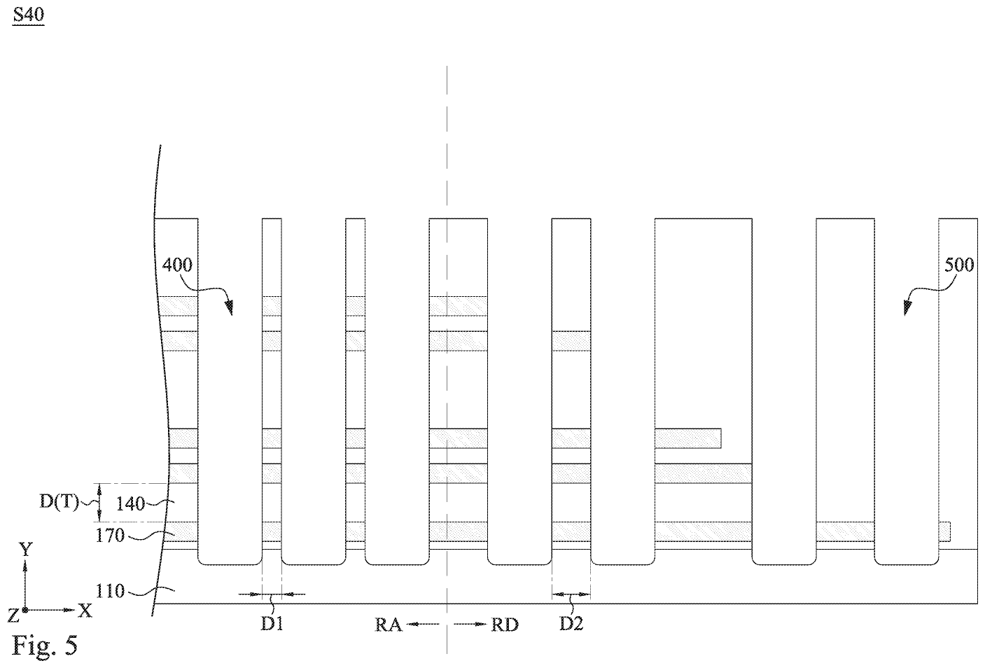

Reference is made to FIG. 5, which is a cross-sectional view of step S40 of forming the semiconductor structure 100. In step S40, at least one first trench 400 is formed on the array region RA of a substrate 110, and at least one second trench 500 is formed on the dummy region RD of a substrate 110. The first trench 400 and the second trench 500 penetrate through the dielectric layer 140 and the insulating layers 170 and further extend into the substrate 110. The first trench 400 and the second trench 500 are formed by an etching process, but the present disclosure is not limited in this regard. In some embodiments of the present disclosure, a number of the first trench 400 is plural, and a number of the second trench 500 is plural, and a distribution density of the first trench 400 is higher than a distribution density of the second trench 500. In detail, a distance D1 between each of the first trenches 400 is smaller than a distance D2 between each of the second trenches 500.

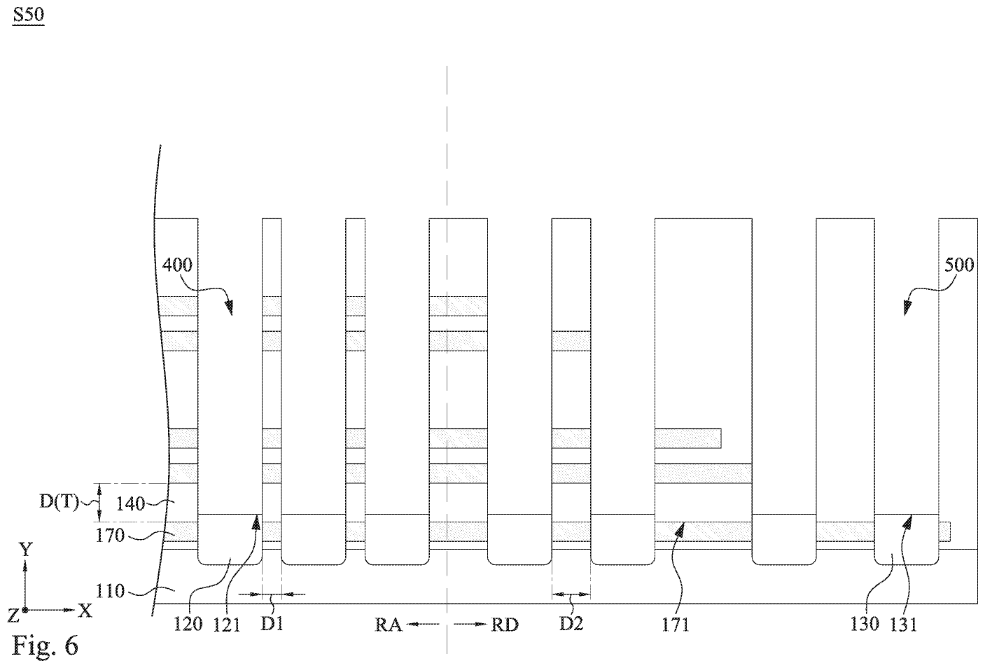

Reference is made to FIG. 6, which is a cross-sectional view of step S50 of forming the semiconductor structure 100. In step S50, a first conductive structure 120 is formed in the first trench 400, and a second conductive structure 130 is formed in the second trench 500. The insulating layers 170, the conductive structures (including the first conductive structure 120 and the second conductive structure 130), and the trenches (including the first trench 400 and the second trench 500) extend in directions perpendicular to each other. As shown in FIG. 6, the insulating layers 170 extend along the X axis, the trenches extend along the Y axis, and the conductive structures extend along the Z axis. In some embodiments of the present disclosure, a top surface 121 of the first conductive structure 120 and a top surface 131 of the second conductive structure 130 are higher than a top surface 171 of the bottommost layer of the insulating layers 170, but the present disclosure is not limited in this regard.

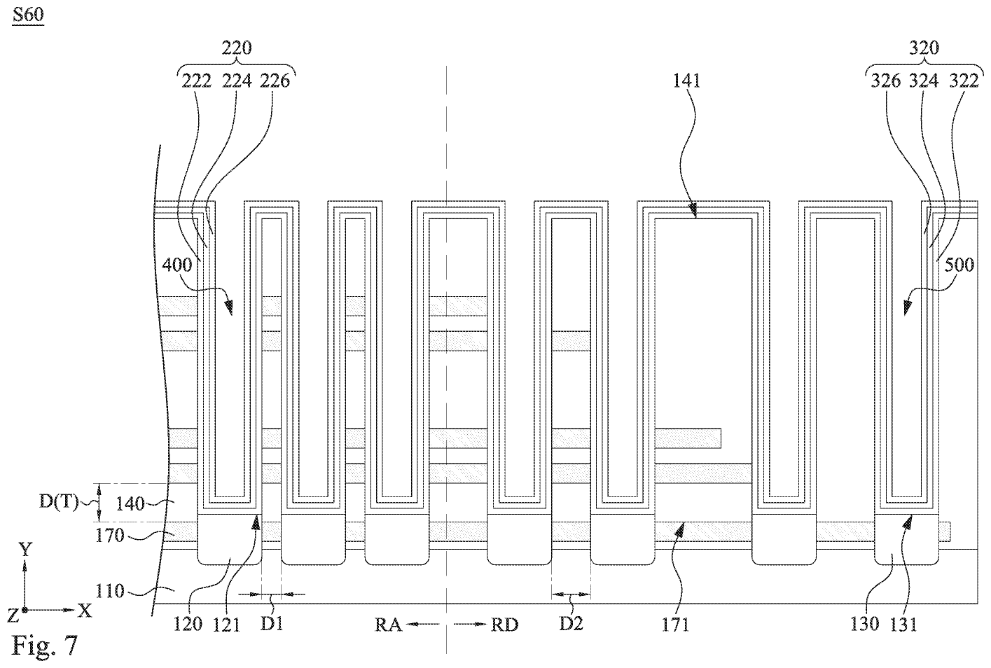

Reference is made to FIG. 7, which is a cross-sectional view of step S60 of forming the semiconductor structure 100. In step S60, a first memory structure layer 220 is conformally formed in the first trench 400 and on a top surface 141 of the dielectric layer 140. In detail, a first blocking layer 222 is conformally formed in the first trench 400 and on the top surface 141 of the dielectric layer 140, a first memory storage layer 224 is conformally formed on the first blocking layer 222, and a first tunneling layer 226 is then conformally formed on the first memory storage layer 224. After the first tunneling layer 226 is formed, the first memory structure layer 220 including the first blocking layer 222, the first memory storage layer 224, and the first tunneling layer 226 is provided. Similarly, a second memory structure layer 320 is conformally formed in the second trench 500 and on the top surface 141 of the dielectric layer 140. In detail, a second blocking layer 322 is conformally formed in the second trench 500 and on the top surface 141 of the dielectric layer 140, a second memory storage layer 324 is conformally formed on the second blocking layer 322, and a second tunneling layer 326 is then conformally formed on the second memory storage layer 324. After the second tunneling layer 326 is formed, the second memory structure layer 320 including the second blocking layer 322, the second memory storage layer 324, and the second tunneling layer 326 is provided. In some embodiments of the present disclosure, the first memory structure layer 220 and the second memory structure layer 320 are formed simultaneously in the same process, and thus may be interconnected with each other on the top surface 141 of the dielectric layer 140.

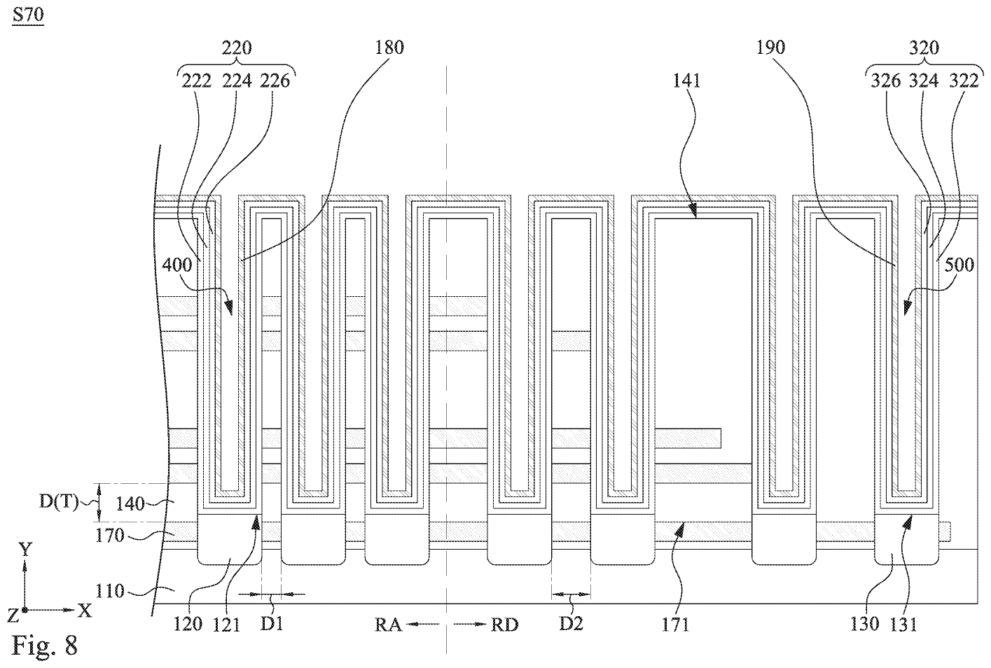

Reference is made to FIG. 8, which is a cross-sectional view of step S70 of forming the semiconductor structure 100. In step S70, a first sacrificial layer 180 is conformally formed on the first memory structure layer 220, and a second sacrificial layer 190 is conformally formed on the second memory structure layer 320. In some embodiments of the present disclosure, the first sacrificial layer 180 and the second sacrificial layer 190 may be made of a material including silicon oxide or other dielectric, but the present disclosure is not limited in this regard. Furthermore, the first sacrificial layer 180 and the second sacrificial layer 190 are formed simultaneously in the same process, and thus may be interconnected with each other over the top surface 141 of the dielectric layer 140.

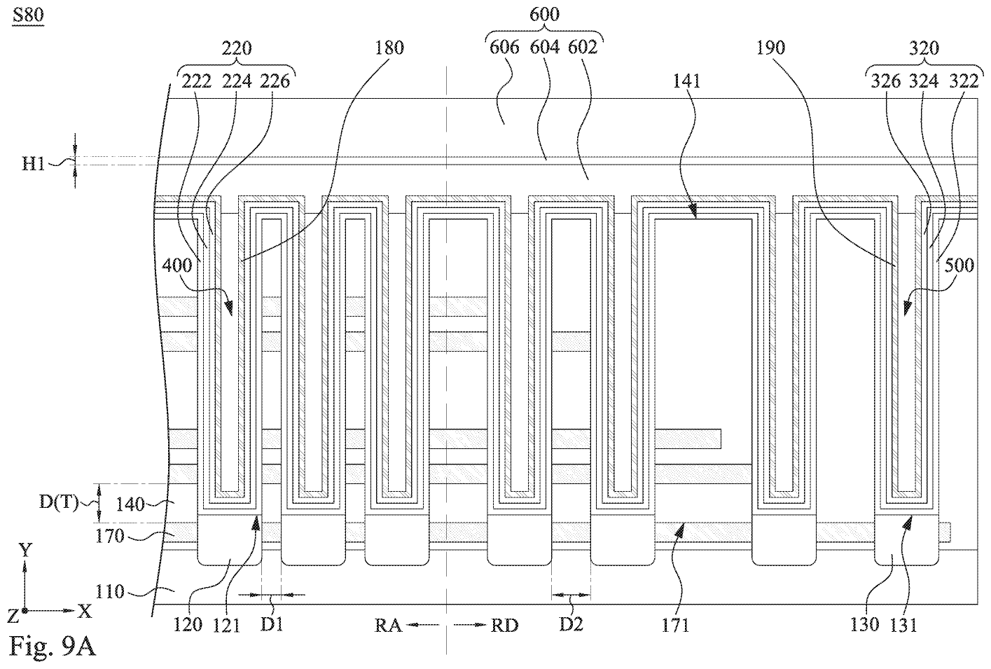

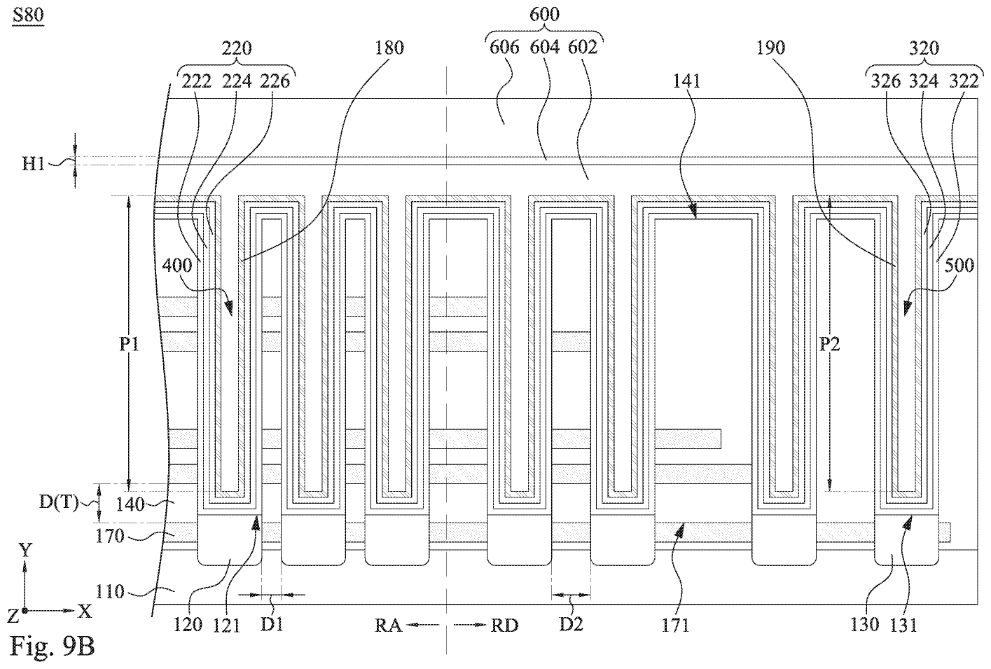

Reference is made to FIG. 9A, which is a cross-sectional view of step S80 of forming the semiconductor structure 100. In step S80, a mask stack 600 is disposed on the array region RA and the dummy region RD of the substrate 110 to cover the first trench 400, the first memory structure layer 220, and the first sacrificial layer 180 as well as the second trench 500, the second memory structure layer 320, and the second sacrificial layer 190. The mask stack 600 includes a patterning layer 602, an antireflective coating layer 604, and a photoresist layer 606. In detail, the patterning layer 602 is disposed on the array region RA and the dummy region RD, the antireflective coating layer 604 is disposed on the patterning layer 602, and the photoresist layer 606 is then disposed on the antireflective coating layer 604.

The patterning layer 602 may be an organic hard mask which is also referred to as an advanced patterning film (APF). The patterning layer 602 has a poor fill-in characteristic such that the first trench 400 and the second trench 500 covered by which may not be easily filled up. As shown in FIG. 9A, the patterning layer 602 is only shallowly filled in the first trench 400 and the second trench 500. As a result, the patterning layer 602 can be easily removed in a subsequent process. The antireflective coating layer 604 may prevent reflections of an ultraviolet (UV) radiation that activates the photoresist layer 606. The antireflective coating layer 604 may further enhance the adhesion between the patterning layer 602 and the photoresist layer 606. A height H1 of the antireflective coating layer 604 is in a range between about 600 Å and 900 Å, but the present disclosure is not limited in this regard. A resist pattern on the photoresist layer 606 is used to define the antireflective coating layer 604 which in return is used to define the patterning layer 602.

FIG. 9B is a cross-sectional view of a process at various stages of a manufacturing method of a semiconductor structure 100 according to another embodiment of the present disclosure. As shown in FIG. 9B, the first trench 400 and the second trench 500 shown in FIG. 9A are being totally filled with the patterning layer 602. However, the present disclosure is not limited on this regard, a depth P1 of the patterning layer 602 filled in the first trench 400 and a depth P2 of the patterning layer 602 filled in the second trench 500 may be adjusted by designers as long as the patterning layer 602 in the first trench 400 and the second trench 500 can be totally removed in the subsequent process.

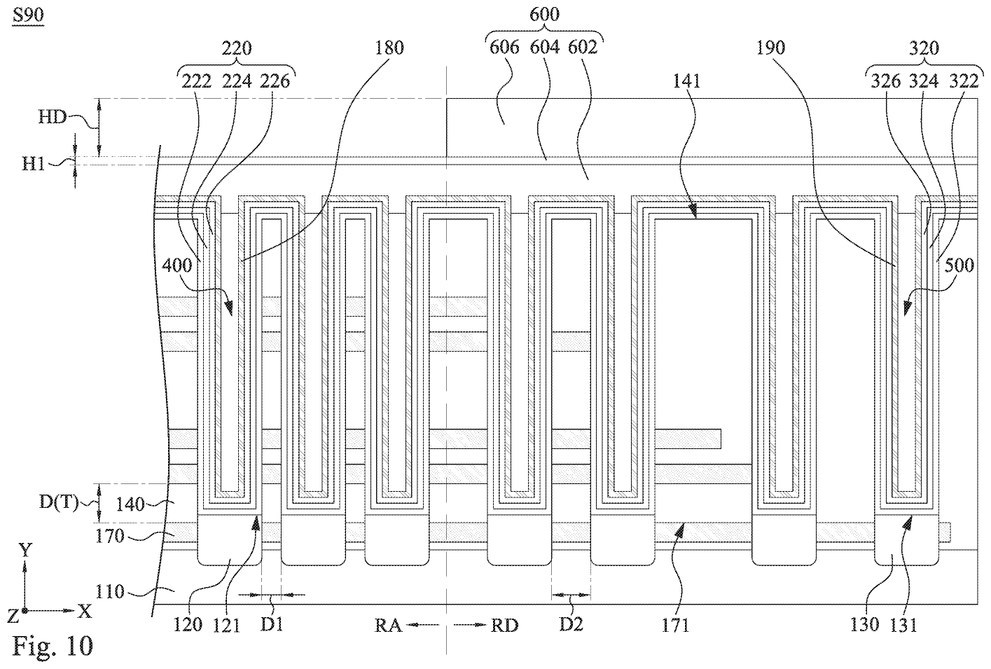

Reference is made to FIG. 10, which is a cross-sectional view of step S90 of forming the semiconductor structure 100. In step S90, an ultraviolet radiation is provided to irradiate toward the photoresist layer 606, such that a portion of the photoresist layer 606 on the array region RA is removed and a portion of the antireflective coating layer 604 on the array region RA is exposed, resulting in a height difference HD between a portion of the mask stack 600 on the array region RA and a portion of the mask stack 600 on the dummy region RD.

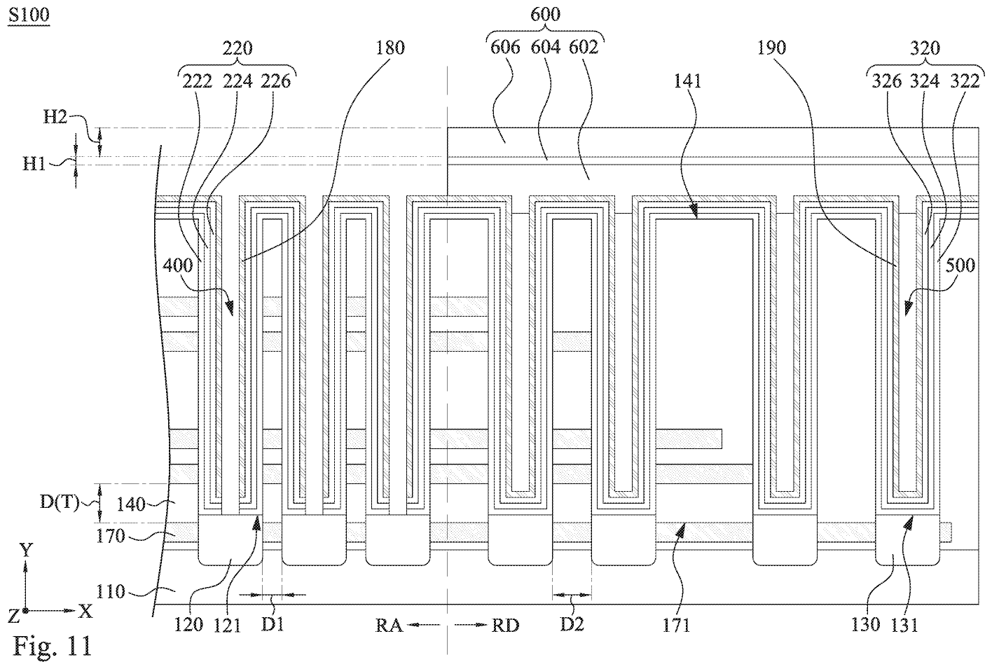

Reference is made to FIG. 11, which is a cross-sectional view of step S100 of forming the semiconductor structure 100. In step S100, a portion of the antireflective coating layer 604 and a portion of the patterning layer 602 on the array region RA are removed by an etching process, such that the first trench 400 and the first sacrificial layer 180 are exposed. After that, the etching process is continuously performed to remove a bottom portion of the first sacrificial layer 180 and a bottom portion of the first memory structure layer 220 in the first trench 400, such that the first trench 400 is deepened, and the first conductive structure 120 is exposed by the first memory structure layer 220 and the first sacrificial layer 180. During the etching process in step S100, a top portion of the photoresist layer 606 disposed on the dummy region RD is simultaneously removed, resulting in a reduction in height H2 of the photoresist layer 606 after the etching process.

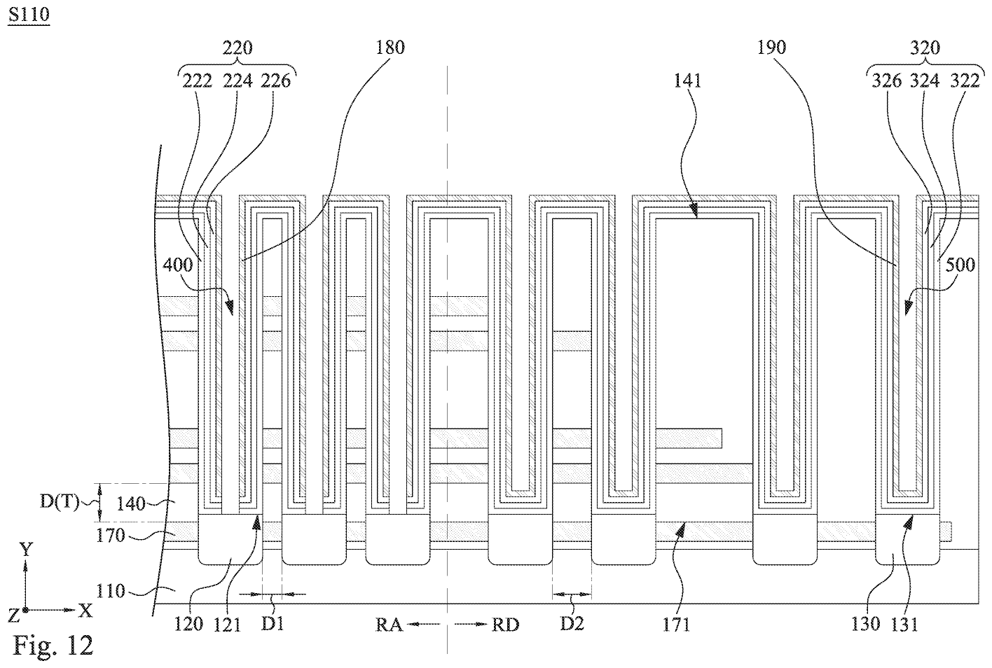

Reference is made to FIG. 12, which is a cross-sectional view of step S110 of forming the semiconductor structure 100. In step S110, the remaining mask stack 600 including the patterning layer 602, the antireflective coating layer 604, and the photoresist layer 606 on the dummy region RD are removed by a dry etching process or a wet etching process, resulting in an exposure of the second trench 500 and the second sacrificial layer 190. After step S110, the first conductive structure 120 is exposed from the first trench 400 while the second conductive structure 130 is covered by the second sacrificial layer 190 and the second memory structure layer 320 in the second trench 500.

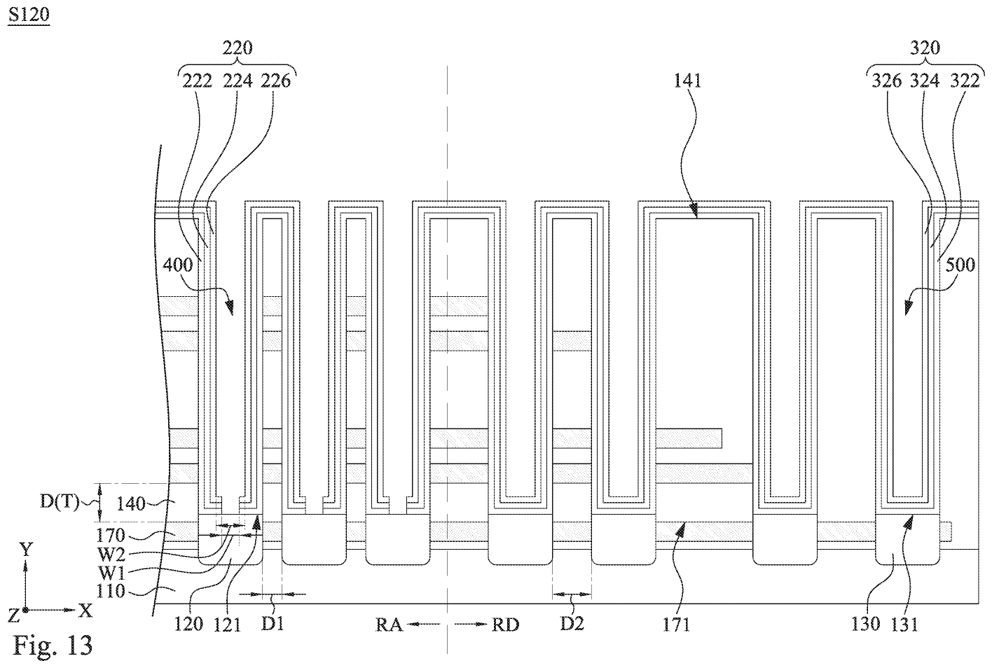

Reference is made to FIG. 13, which is a cross-sectional view of step S120 of forming the semiconductor structure 100. In step S120, the first sacrificial layer 180 and the second sacrificial layer 190 are removed by a selective etching process, such that the first memory structure layer 220 and the second memory structure layer 320 are respectively exposed from the first trench 400 and the second trench 500. The selective etching process may be a may be a wet etching process or a dry etching process, but the present disclosure is not limited in this regard. Since the bottom portion of the first memory structure layer 220 has been first removed in step S100, the removal of the remaining first sacrificial layer 180 in the first trench 400 in step S120 results in a width difference between a bottom portion of the first trench 400 and a top portion of the first trench 400. In detail, a width W1 of the bottom portion of the first trench 400 is smaller than a width W2 of the top portion of the first trench 400.

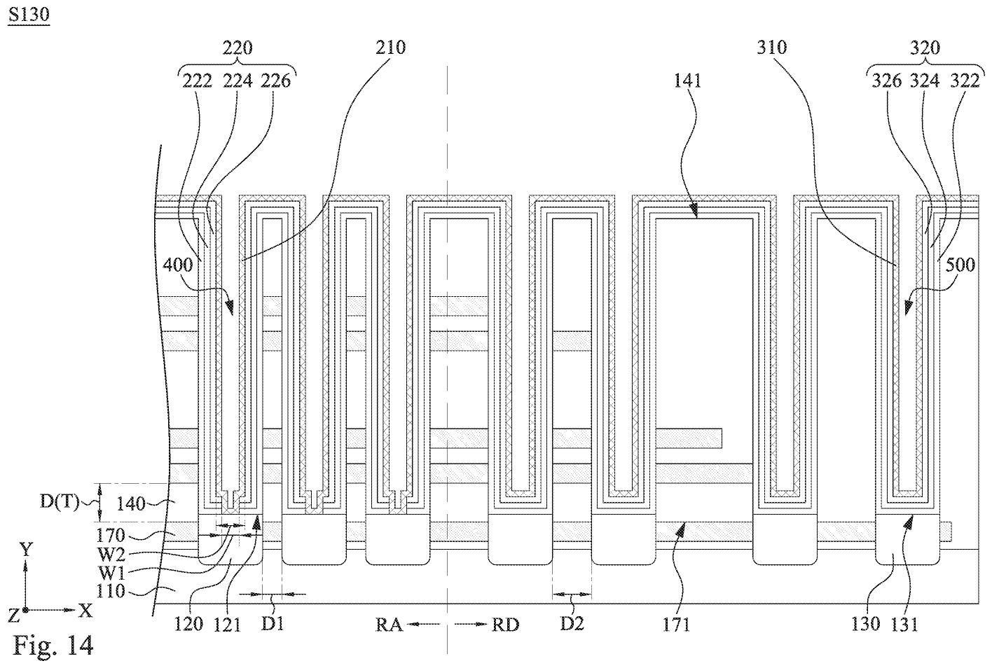

Reference is made to FIG. 14, which is a cross-sectional view of step S130 of forming the semiconductor structure 100. In step S130, a first channel layer 210 is conformally formed on the first memory structure layer 220, and a second channel layer 310 is conformally formed on the second memory structure layer 320. Since the first conductive structure 120 has been exposed from the first trench 400 in step S100, the first channel layer 210 is further formed on the first conductive structure 120 and in contact with the first conductive structure 120. On the contrary, the second channel layer 310 is formed to be isolated from the second conductive structure 130 by the second memory structure layer 320 in the second trench 500.

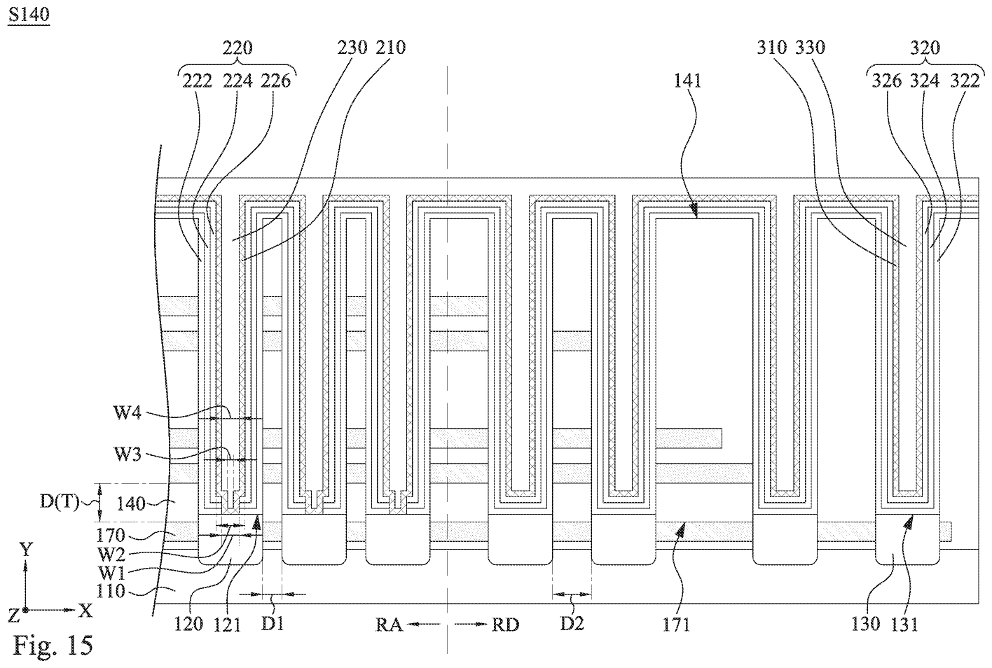

Reference is made to FIG. 15, which is a cross-sectional view of step S140 of forming the semiconductor structure 100. In step S140, a first isolation structure 230 is formed on the first channel layer 210 and filled in the first trench 400, and the second isolation structure 330 is formed on the second channel layer 210 and filled in the second trench 500. Additionally, a width W3 of a bottom portion of the first isolation structure 230 is smaller than a width W4 of a top portion of the first isolation structure 230 due to the width difference (W2-W1) between the bottom portion of the first trench 400 and the top portion of the first trench 400. In some embodiments of the present disclosure, the first isolation structure 230 and the second isolation structure 330 are formed simultaneously in the same process, and thus are interconnected with each other over the top surface 141 of the dielectric layer 140.

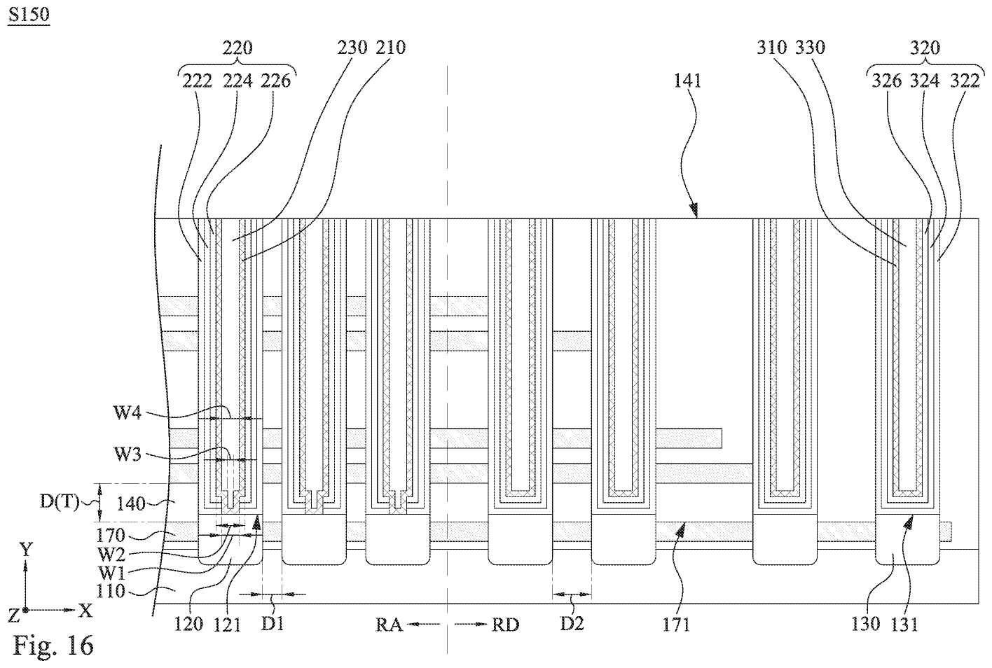

Reference is made to FIG. 16, which is a cross-sectional view of step S150 of forming the semiconductor structure 100. In step S150, a top portion of the first isolation structure 230, a top portion of the first channel layer 210, and a top portion of the first memory structure layer 220 which are exceeded outside the first trench 400 as well as a top portion of the second isolation structure 330, a top portion of the second channel layer 310, and a top portion of the second memory structure layer 320 which are exceeded outside the second trench 500 are removed by a planarization process such as a chemical-mechanical polishing (CMP) process, such that the top surface 141 of the dielectric layer 140 is exposed.

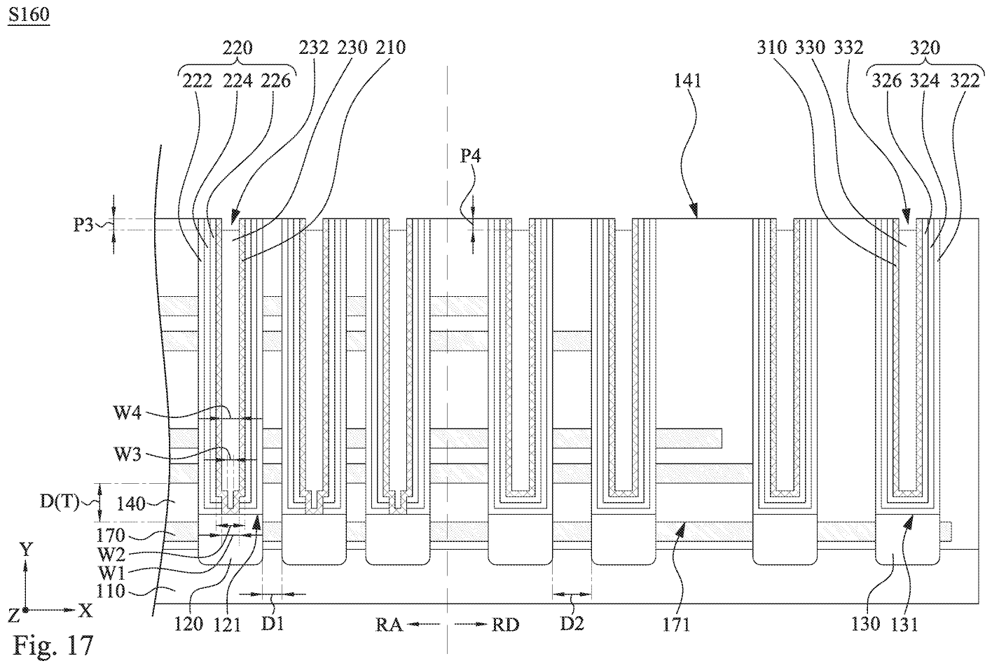

Reference is made to FIG. 17, which is a cross-sectional view of step S160 of forming the semiconductor structure 100. In step S160, a top portion of the first isolation structure 230 and a top portion of the second isolation structure 330 are removed by an etching process, thereby forming a first etched space 232 and a second etched space 332 shown in FIG. 17. As for an etching depth P3 of the first isolation structure 230 in the first trench 400 and an etching depth P4 of the second isolation structure 330 in the second trench 500, the etching process may stop at a desired position by a time mode control.

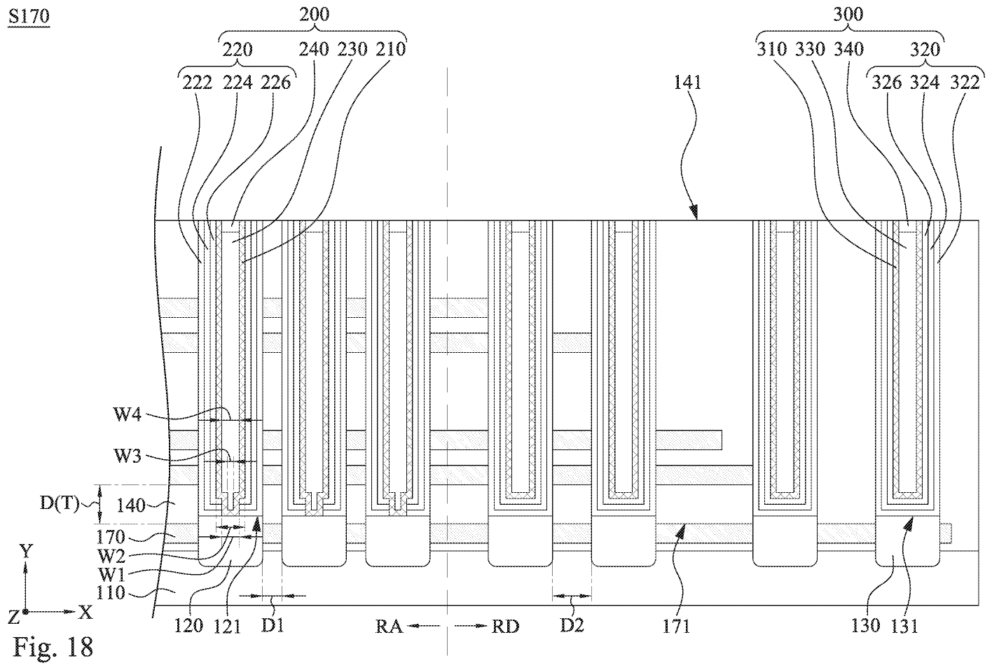

Reference is made to FIG. 18, which is a cross-sectional view of step S170 of forming the semiconductor structure 100. In step S170, the first etched space 232 is then refilled with a material including the same material as that of the first channel layer 210, such as doped polysilicon, to form a first conductive plug layer 240. Similarly, the second etched space 332 is then refilled with a material including the same material as that of the second channel layer 310, such as doped polysilicon, to form a second conductive plug layer 340. As a result, a replacement of the top portion of the first isolation structure 230 with the first conductive plug layer 240 and a replacement of the top portion of the second isolation structure 330 with the second conductive plug layer 240 are completed. As such, the first conductive plug layer 240 and the second conductive plug layer 340 are respectively disposed on the first isolation structure 230 and the second isolation structure 330. Furthermore, the first conductive plug layer 240 is in contact with the first channel layer 210, and the second conductive plug layer 340 is in contact with the second channel layer 310.

After step S170, a first memory structure 200 including the first memory structure layer 220, the first channel layer 210, the first isolation structure 230, and the first conductive plug layer 240 is formed over the array region RA of the substrate 110 and penetrating through the insulating layers 170 and the dielectric layer 140, and a second memory structure 300 including the second memory structure layer 320, the second channel layer 310, the second isolation structure 330, and the second conductive plug layer 340 is formed over the dummy region RD of the substrate 110 and penetrating through the insulating layers 170 and the dielectric layer 140.

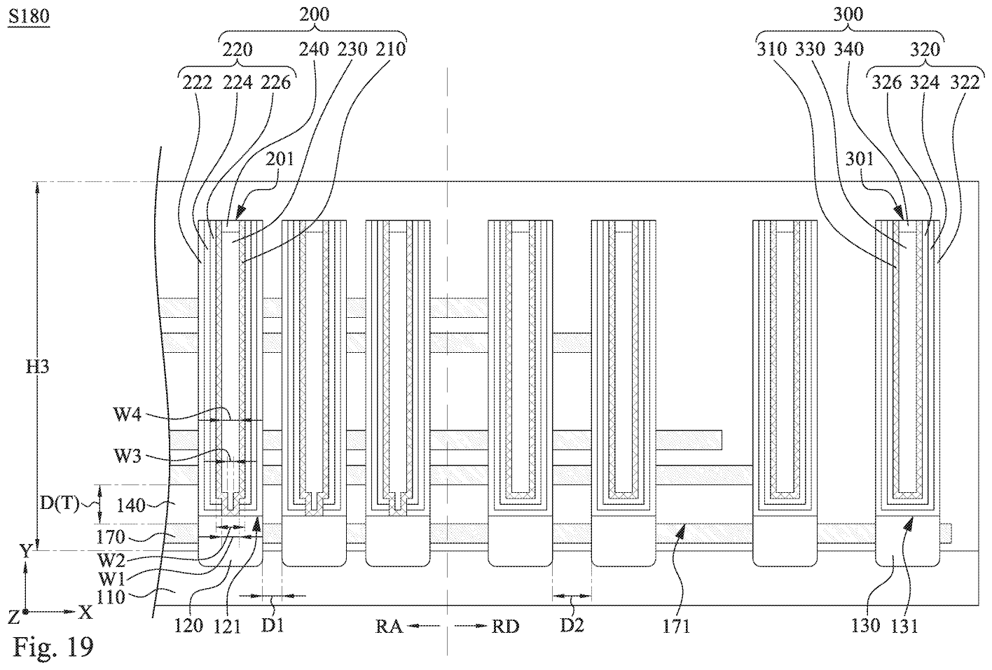

Reference is made to FIG. 19, which is a cross-sectional view of step S180 of forming the semiconductor structure 100. In step S180, the material of the dielectric layer 140 is further disposed on a top surface 201 of the first memory structure 200 and a top surface 301 of the second memory structure 300, such that a height H3 of the dielectric layer 140 is increased, and the first memory structure 200 and the second memory structure 300 are covered by a top portion of the dielectric layer 140. As such, the first memory structure 200 and the second memory structure 300 are ensured to be isolated from each other.

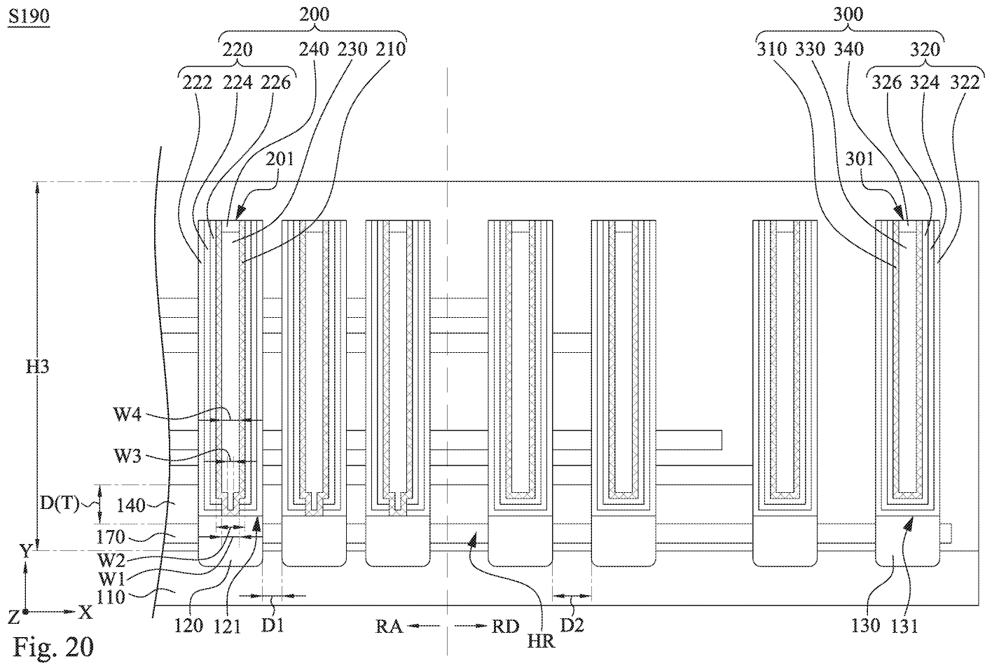

Reference is made to FIG. 20, which is a cross-sectional view of step S190 of forming the semiconductor structure 100. In step S190, the insulating layers 170 embedded in the dielectric layer 140 are then being removed by a selective etching process to form a plurality of hollow regions HR. In some embodiments of the present disclosure, the selective etching process may be a chemical etching process in hot phosphoric acid removing the insulating layers 170 which may be made of a material including silicon nitride. During the selective etching process, the first memory storage layer 224 and the second memory storage layer 324 which may also be made of a material including silicon nitride are being protected. As a result, the first memory storage layer 224 is preserved between the first blocking layer 222 and the first tunneling layer 226, and the second memory storage layer 324 is preserved between the second blocking layer 322 and the second tunneling layer 326.

Since the hollow regions HR formed in step S190 may make the dielectric layer 140 vulnerable and easily crushed, the second memory structure 300 may serve as a pillar to sustain the dielectric layer 140 during the removal of the insulating layers 170.

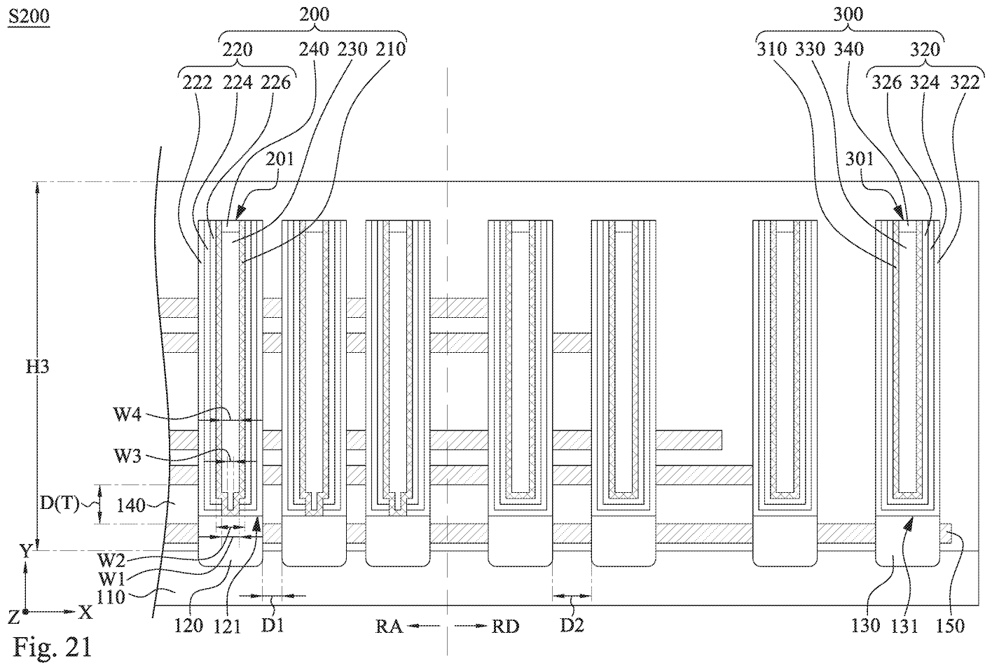

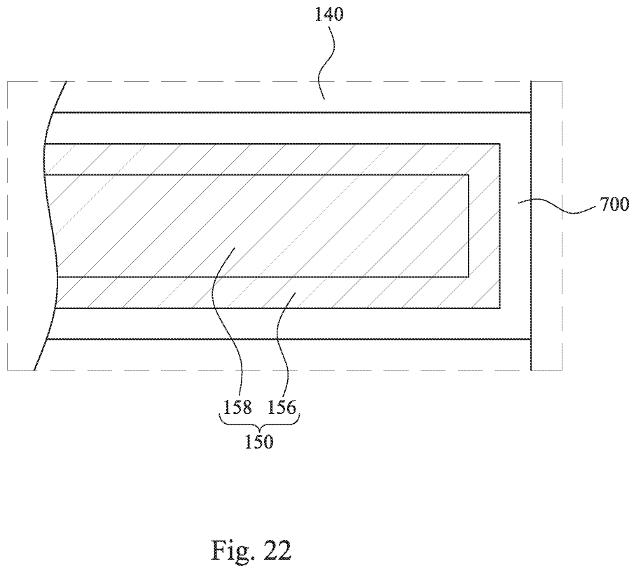

FIG. 22 is a partial enlargement diagram of FIG. 21. Reference is made to FIG. 21, which is a cross-sectional view of step S200 of forming the semiconductor structure 100. In step S200, a plurality of conductive layers 150 are disposed in the hollow regions HR and embedded in the dielectric layer 140, thereby resulting in a replacement of the insulating layers 170 with the conductive layers 150. As shown in FIG. 22, each of the conductive layers 150 includes a barrier layer 156 and a metal layer 158. The barrier layer 156 is conformally disposed on sidewalls of the dielectric layer 140, and the metal layer 158 is disposed on the barrier layer 156. The conductive layers 150 may be disposed by a chemical vapor deposition (CVD) process. In some embodiments of the present disclosure, the barrier layer 156 may be made of a material including titanium nitride, and the metal layer 158 may be made of a material including tungsten or other metal, but the present disclosure is not limited in this regard.

In some embodiments of the present disclosure, the semiconductor structure 100 may further include a plurality of high-k dielectric layers 700. The high-k dielectric layers 700 are disposed between the dielectric layer 140 and the barrier layers 156, shown in FIG. 22. For example, the high-k dielectric layers 700 may be disposed before the conductive layers 150 are disposed. Furthermore, the high-k dielectric layers 700 may be made of a material including aluminum oxide or other dielectric.

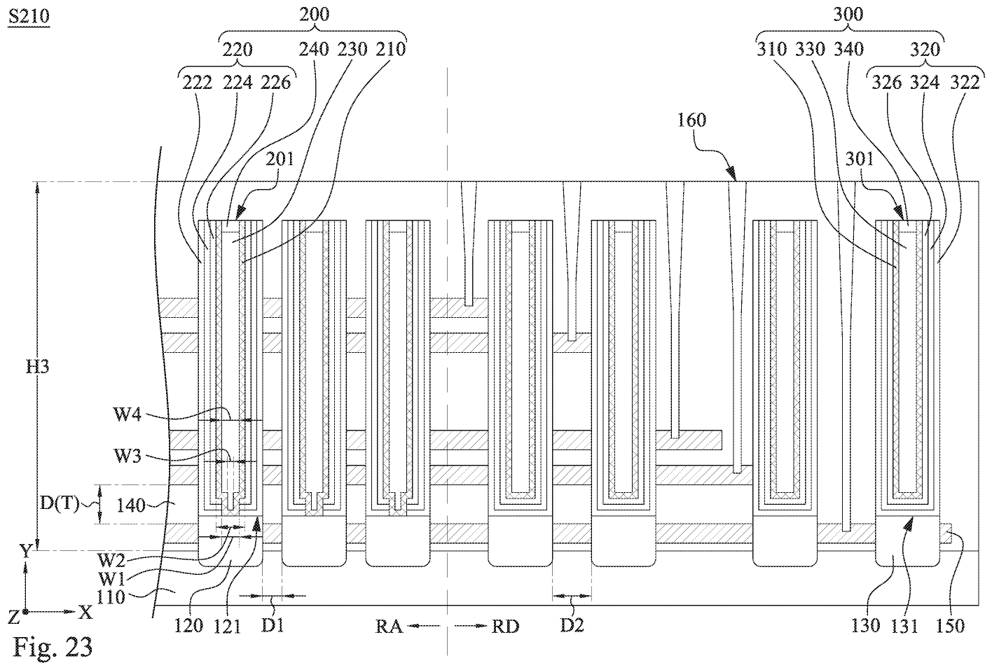

Reference is made to FIG. 23, which is a cross-sectional view of step S210 of forming the semiconductor structure 100. In step S210, at least one contact structure 160 is formed to penetrate through the dielectric layer 140 and be in contact with one of the conductive layers 150. The contact structure 160 is formed on the dummy region RD and entirely separated from the first memory structure 200 and the second memory structure 300. In some embodiments of the present disclosure, a number of the contact structure 160 is plural, and a number of the second memory structure 300 is plural, in which each of the contact structures 160 may be disposed between the first memory structure 200 and the second memory structure 300 or between the second memory structures 300.

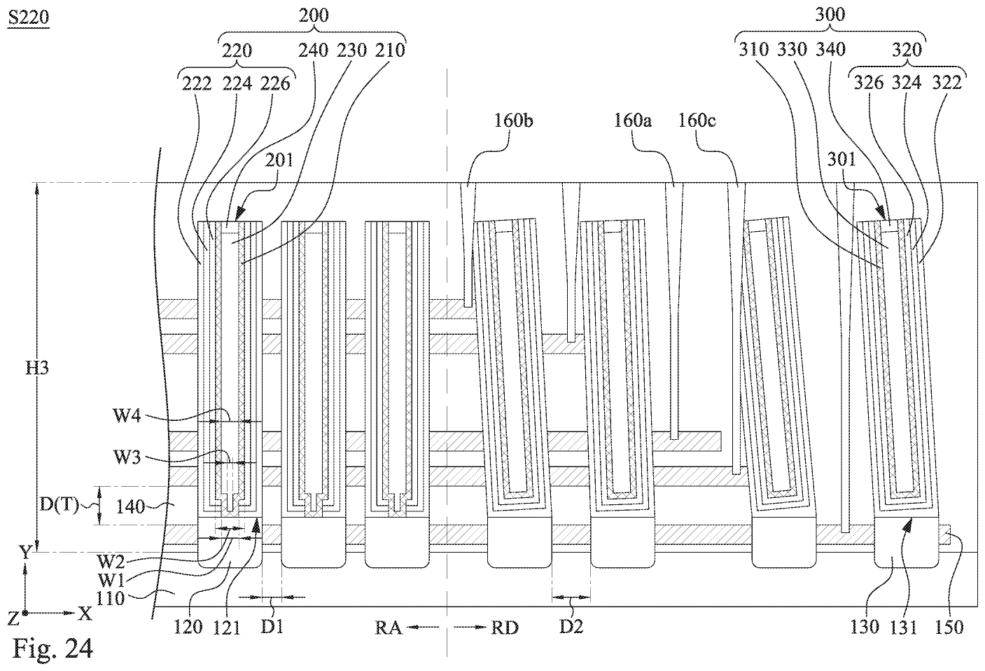

Reference is made to FIG. 24, which is a cross-sectional view of step S220 of forming the semiconductor structure 100. In step S220, the second memory structure 300 suffers a stress due to different material distributions, resulting in a miss alignment and an oblique of the second memory structure 300 as shown in FIG. 24. Therefore, the contact structure 160 may be entirely separated from the second channel layer 310 such as 160a, near the second channel layer 310 such as 160b, or in contact with the channel layer 310 such as 160c. After step S220, the semiconductor structure 100 shown in FIG. 1 is formed. Since the second channel layer 310 of the second memory structure 300 is isolated from the second conductive structure 130, the contact structure 160c in contact with the second channel layer 310 will not cause contact short to the second memory structure 300, and hence fake signals caused by array breakdown and word line leak are prevented.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

1. A semiconductor structure, comprising:
a substrate having an array region and a dummy region;
at least one first conductive structure disposed on the array region;
at least one second conductive structure disposed on the dummy region;
at least one first memory structure disposed on the first conductive structure, wherein the first memory structure comprises a first channel layer, and the first channel layer is in contact with the first conductive structure; and
at least one second memory structure disposed on the second conductive structure, wherein the second memory structure comprises a second channel layer, and the second channel layer is isolated from the second conductive structure.

2. The semiconductor structure of claim 1, wherein a number of the first memory structure is plural, and a number of the second memory structure is plural, and a distribution density of the first memory structures is higher than a distribution density of the second memory structures.

3. The semiconductor structure of claim 1, further comprising:
a dielectric layer disposed on the substrate; and
a plurality of conductive layers embedded in the dielectric layer, wherein the first memory structure and the second memory structure penetrate through the dielectric layer and the conductive layers.

4. The semiconductor structure of claim 3, wherein each of the conductive layers has a first segment and a second segment, the first segments are disposed on the array region, the second segments are disposed on the dummy region, and the second segments are in a staircase configuration.

5. The semiconductor structure of claim 4, further comprising:
at least one contact structure penetrating through the dielectric layer and in contact with the second segment of one of the conductive layers.

6. The semiconductor structure of claim 1, wherein the first memory structure further comprises:
a first memory structure layer;
a first isolation structure, wherein a portion of the first channel layer is between the first memory structure layer and the first isolation structure, and a portion of the first channel layer penetrates through a bottom portion of the first memory structure layer; and
a first conductive plug layer disposed on the first isolation structure, wherein the first conductive plug layer is in contact with the first channel layer.

7. The semiconductor structure of claim 6, wherein the first memory structure layer comprises:
a first blocking layer disposed on sidewalls of the conductive layers and the dielectric a first memory storage layer disposed on the first blocking layer; and
a first tunneling layer disposed on the first memory storage layer.

8. The semiconductor structure of claim 1, wherein the second memory structure further comprises:
a second memory structure layer;
a second isolation structure, wherein the second channel layer is between the second memory structure layer and the second isolation structure; and
a second conductive plug layer disposed on the second isolation structure, wherein the second conductive plug layer is in contact with the second channel layer.

9. The semiconductor structure of claim 8, wherein the second memory structure layer comprises:
a second blocking layer disposed on sidewalls of the conductive layers and the dielectric layer and on the second conductive structure;
a second memory storage layer disposed on the second blocking layer; and
a second tunneling layer disposed on the second memory storage layer.

10. The semiconductor structure of claim 1, wherein the first conductive structure and the second conductive structure are epitaxial structures.

11-20. (canceled)

21. A semiconductor structure, comprising:
a substrate having an array region and a dummy region;
at least one first conductive structure disposed on the array region;
at least one second conductive structure disposed on the dummy region;
at least one first memory structure disposed on the first conductive structure, wherein the first memory structure has a first blocking layer and a first channel layer, the first blocking layer is in contact with the first conductive structure, and a portion of the first channel layer penetrates through the first blocking layer; and
at least one second memory structure disposed on the second conductive structure, wherein the second memory structure has a second blocking layer and a second channel layer, the second blocking layer is in contact with the second conductive structure, and the second channel layer is spaced apart from the second conductive structure by the second blocking layer.

22. The semiconductor structure of claim 21, wherein the second memory structure is oblique relative to the first memory structure.

23. The semiconductor structure of claim 21, further comprising:
at least one contact structure in contact with the second channel layer of the second memory structure.

24. The semiconductor structure of claim 23, wherein the contact structure penetrates through the second channel layer of the second memory structure.

25. The semiconductor structure of claim 21, further comprising:
a dielectric layer disposed on the substrate; and
a plurality of conductive layers embedded in the dielectric layer, wherein each of the conductive layers has a first segment and a second segment, the first memory structure penetrates through the first segments, the second memory structure penetrates through the second segments, and the second segments are in a staircase configuration.

26. The semiconductor structure of claim 25, wherein the first blocking layer is disposed on sidewalls of the conductive layers and the dielectric layer.

27. A semiconductor structure, comprising:
a substrate having an array region and a dummy region;
at least one first conductive structure on the array region;
at least one second conductive structure on the dummy region;
at least one first memory structure disposed on the first conductive structure, wherein the first memory structure comprises a first channel layer on the first conductive structure; and
at least one second memory structure disposed on the second conductive structure, wherein the second memory structure comprises a second channel layer that is spaced apart from the second conductive structure, and a bottom of the first channel layer is lower than a bottom of the second channel layer.

28. The semiconductor structure of claim 27, wherein the second memory structure is oblique relative to the first memory structure.

29. The semiconductor structure of claim 27, further comprising:
at least one contact structure penetrating through the second channel layer of the second memory structure.

30. The semiconductor structure of claim 27, wherein a number of the first memory structure is plural, and a number of the second memory structure is plural, and a distribution density of the first memory structures is higher than a distribution density of the second memory structures.
